(19) United States
(12) Patent Application Publication
(10) Pub. No.: US 2013/0267089 A1
(43) Pub. Date: Oct. 10, 2013

(54) FILM FOR FILLING THROUGH HOLE INTERCONNECTS AND POST PROCESSING FOR INTERCONNECT SUBSTRATES

(71) Applicant: HENKEL CORPRATION, Rocky Hill, CT (US)

(72) Inventors: Daniel Maslyk, Rancho Santa Margarita, CA (US); George Carson, Lake Forest, CA (US); Raj Peddi, Irvine, CA (US)

(73) Assignee: HENKEL CORPRATION, Rocky Hill, CT (US)

(21) Appl. No.: 13/827,698

(22) Filed: Mar. 14, 2013

Related U.S. Application Data
(60) Provisional application No. 61/619,955, filed on Apr. 4, 2012.

(51) Int. Cl. H01R 43/00; H01L 21/768

(52) U.S. Cl. CPC H01R 43/00; H01L 21/76877
USPC 438/637; 156/60; 156/285; 216/20; 205/78

(57) ABSTRACT

A method for filling through hole interconnects in a substrate used in the manufacture of electronic devices uses a film filler material. The film comprises a resin matrix filled with conductive and/or dielectric particles, and can be a single or multi-layer film. The method comprises providing a substrate for an electronic device having one or more through hole interconnects; providing a film comprising at least one film filler material for the through hole interconnects; deposing the film filler material over the substrate; and pressing the film filler material into the through hole interconnects.

### BACKGROUND OF THE INVENTION

This invention relates to a film that can be used to deposit a dielectric coating and/or a metal coating within a through hole interconnect in a substrate used in electronic devices, and to a process for applying that film. This invention also relates to methods for processing the substrates post coating the through hole interconnects.

To meet the demand for faster and smaller electronic devices, the population of integrated circuits on semiconductor substrates is becoming ever more dense. The use, however, of a single semiconductor substrate in a planar two-dimensional structure for integrated circuits limits the ultimate circuit density. Consequently, the electronics packaging industry has turned to vertical integration, that is, the stacking of semiconductor substrates with integrated circuits into three dimensional packages.

The semiconductor substrate or wafer is prepared, conventionally, from a semiconductor material, typically silicon, gallium arsenide, germanium, or similar compound semiconductor materials. The stacked semiconductors are electrically interconnected, in one approach, by way of holes etched through the semiconductor material. These holes are generally known as through holes, through hole interconnects, vias, or through silicon vias. In order to act as electrical conductors, they are filled with a conductive material, usually a metal. Some through hole interconnects may also have a dielectric layer deposited first, with the conductive metal deposited over the dielectric. The sidewalls can be vertical or sloped, straight or rounded. The openings can be round or rectangular.

A method used for deposition of the dielectric layer is chemical vapor deposition. The dielectric layer is usually about 1-2 μm thick. Methods used for deposition of the metal layer include electroless plating, pulse plating, and direct electroplating, using, for example, vacuum sputtering or physical vapor deposition. Suitable metals include, for example, aluminum, copper, silver, gold, nickel, and alloys. The metal layer is usually about 0.8 to 1.2 μm thick.

In addition to through hole interconnects in semiconductor substrates, through hole interconnects can also be formed in dielectric substrates and other types of material using the same methods as described above.

These deposition methods are chemically harsh, relatively slow, and relative costly. Furthermore, these methods have limitations with respect to the aspect ratio of the diameter to the depth of the through hole interconnect. Alternative deposition methods would be an advantage.

### SUMMARY OF THE INVENTION

This invention is a method for filling through hole interconnects (hereinafter, referred to as “through holes”) in a substrate for use in the manufacture of electronic devices. The filler material is a film comprising a resin matrix filled with conductive particles, or a multi-layer film in which at least one layer is a film comprising a resin matrix filled with conductive particles and at least one other layer is a film comprising a resin matrix filled with dielectric compounds. Hereinafter, the film layer comprising a resin matrix filled with dielectric compounds will also mean or include a film layer comprising a dielectric resin.

The method comprises providing a substrate for an electronic device having one or more through hole interconnects; providing a film comprising at least one filler material for the through hole interconnects, hereinafter referred to as “filler material”; deposing the filler material over the substrate and pressing the filler material into the through hole interconnects.

In further embodiments this invention relates to one or more methods for processing the substrates post coating the through hole interconnects. These post coating embodiments will be described later in this specification.

### BRIEF DESCRIPTION OF THE FIGURES

FIGS. 1 though 4 depict post through hole coating processes for making redistribution or interconnect layers on a substrate for use in electronic devices.

FIG. 1 depicts a process for using through hole filler as a seed plate for plating a metal interconnect layer on a substrate.

FIG. 2 depicts a process for forming a first layer interconnect after disposing a dielectric imprint mask on the substrate before the through holes are filled.

FIG. 3 depicts a process for using protruding through hole filler as a bonding cap and eliminating the etch back of a substrate around the bonding cap.

FIG. 4 depicts the use of a laminate composite comprising a film of filler material and a metal foil to make a redistribution layer.

### DETAILED DESCRIPTION OF THE INVENTION

Substrates that contain through holes are typically crystalline semiconductor substrates; they can also be glass or plastic substrates, which are used as interposers. These substrates are known in the art and are used in various electronic devices in accordance with the design and function of the device.

The through holes may pass all the way through the substrate or only part of the way. The holes that pass only part of the way through the substrate are later etched out to make a through hole that passes all the way through the substrate.

In one embodiment the filler material is in the form of a film comprising a resin matrix and conductive or non-conductive particles. The resin matrix can be formed from those resins known in the art useful as adhesives, sealants or coatings. Suitable resins include acrylic, acrylate, epoxy, oxetane, maleimide, vinyl ether and carboxyl-terminated butadiene nitrile rubber resins, and other resins having carbon to carbon unsaturation. Combinations of these resins may also be used. If the resins are solids, they will be dissolved in solvents. If the resins are liquid, they can be used neat, or with an appropriate amount of solvent to obtain a suitable viscosity.

When the filler material is conductive, it will comprise a resin matrix and conductive particles. Suitable conductive particles include carbon black, graphite, gold, silver, copper, platinum, palladium, nickel, aluminum, silver plated copper, silver plated aluminum, bismuth, tin, bismuth-tin alloy, silver plated fiber, silicon carbide, boron nitride, diamond, alumina, and alloy 42 (a nickel and iron alloy in which nickel is present at 42%). In one embodiment, the conductive particles are selected from the group consisting of silver, silver plated copper, copper, gold, and alloy 42.

When the filler material is a dielectric, it will comprise a resin matrix and non-conductive particles. Suitable nonconductive fillers are particles of vermiculite, mica, wollastonite, calcium carbonate, titania, sand, glass, fused silica, fumed silica, barium sulfate, and halogenated ethylene polymers, such as tetrafluoroethylene, trifluoroethylene, vinylidene fluoride, vinyl fluoride, vinylidene chloride, and vinyl chloride. In some embodiments, the resin matrix itself can be the dielectric.

The resins are blended with the chosen conductive or non-conductive particles until the particles are well dispersed, forming an ink. The ink is milled until the desired fineness of grind is achieved. A fineness of grind of seven microns or less is preferable.

The ink is applied to a carrier substrate in a uniform thickness, and the solvent evaporated off, thereby forming a film from the ink. In some cases, the film is heated to the cure temperature of the resin matrix to cure the resin matrix. In other cases, particularly when the film is conductive, the film is heated to the sintering temperature of the conductive particles used. When ready for use, the carrier substrate is removed from the film, also referred to herein as “filler material”.

After any solvent is evaporated off, the filler particles, either conductive or non-conductive, will comprise from 65% to 95% by weight of the film composition.

In some embodiments, the film can have multiple layers. In one such embodiment, one layer is a conductive filler material, comprising a resin matrix filled with conductive particles; a second layer is a dielectric filler material, comprising a resin matrix filled with dielectric particles. The conductive and dielectric films are laminated together with heat and pressure as needed for an effective lamination. In other embodiments, additional layers to give other properties can be added.

The filler material, either as a single or multi-layer film, is disposed over the substrate having one or more through hole interconnects, and is pressed into the substrate and into the through holes. The amount of pressure to be used will vary with the filler material, size of the through holes, and composition of the substrate. The determination of these variables will be within the expertise of one skilled in the art. In general, the amount of pressure used will be within 0.5 to 15 megapascals.

If a multi-layer film is used, for example, a film containing a dielectric film layer and a conductive film layer, the dielectric layer is contacted to the substrate. In this configuration, the dielectric layer insulates the conductive layer from the substrate. In other embodiments, additional layers can be contemplated, such as a shielded ground or a cover.

If needed, a vacuum can be used from the underside of the through holes to help pull the filler material into and/or through the holes, although generally, vacuum is not needed when there are openings at both ends of the through holes. The application of heat may be used to soften the filler materials and make them more pliable and easier to press. If used, heat will be applied within a range of temperatures up to about 150° C., although higher temperatures may be applied when needed and within the tolerances of the components being used. Vacuum is typically required during the deposition of filler material in through holes for which there is only one opening. In this case, vacuum is applied to evacuate air entrapped within the through holes.

After the filler material is disposed into the through hole interconnects, the resin matrix is usually cured or sintered. This can be done thermally, or by irradiation. The exact curing or sintering conditions will depend on the materials used, and information on those conditions is usually provided by the supplier or will be within the knowledge of the practitioner.

In many cases, conductive filler is allowed to protrude through to the bottom side (also known as the back side) of the substrate to form a contact pad for electrically connecting the substrate to another substrate. The other substrate in this instance is usually a semiconductor wafer before it is singulated into individual semiconductor dies. In prior art embodiments that use plating techniques for filling through holes, after the through holes are filled, the back side of the wafer is etched until the filler material is exposed to form the contact pad. In the process of this invention, the filler material can be pressed into and vacuum suctioned from the through hole to form a sufficiently protuberant contact pad so that the back side of the wafer does not need to be etched. The back side contact pads are used to form multi-die vertical integrated circuits.

In those cases in which the substrate is a glass or plastic interposer, the filler material for the through holes will be applied, typically, before any routing or circuitry is formed on the substrate. In those cases in which the substrate is an active semiconductor, the filler material can be applied either before or after the active circuitry is formed. The order of fabrication is within the expertise and determination of the manufacturer.

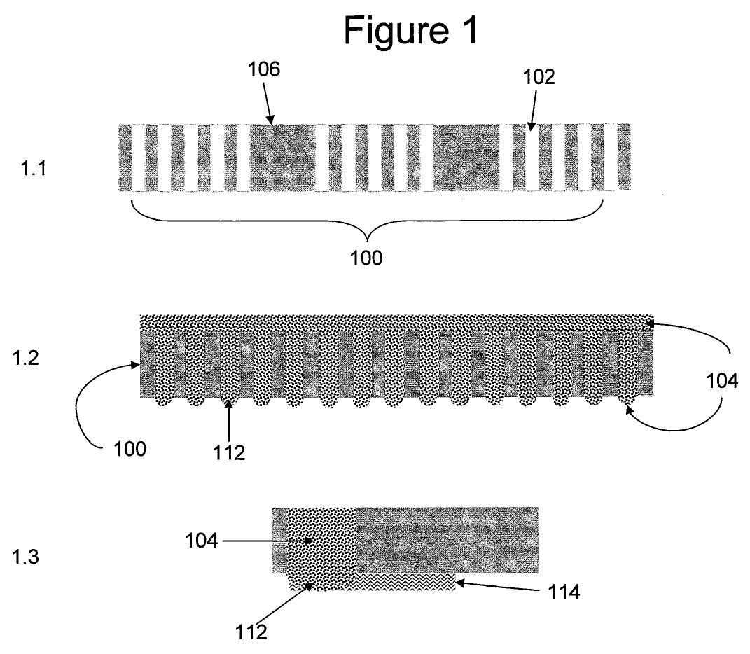

Any filler material left on the surface of the substrate can be removed mechanically, such as, by grinding. Alternatively, the filler material remaining on the substrate can be used in processing steps performed after the through holes are coated. Processing steps in which the excess filler material are used are described here. In these steps, “mask” will refer to plating, etching, or imprint masks, as appropriate to the method being described. Drawing 1.1 in FIG. 1 is the substrate with through holes before the through holes are coated, and is the starting point for the processes depicted in FIGS. 1 though 4.

In one post through hole interconnect process, conductive filler material for the through holes is brought completely through the interconnects and out the bottom side so as to form a cap, the cap being of sufficient protuberance so that etch-back of the substrate is not required to expose the cap. The cap performs as a bonding pad for electrically connecting another substrate. Referring to FIG. 1, drawing 1.1 shows a substrate 100, with through holes 102, and substrate surface 106, before the through holes are filled; drawing 1.2 shows a substrate with filler material 104 deposed over the surface of the substrate and protruding through the through holes of the substrate, forming a cap 112, which can act as a bonding pad; drawing 1.3 shows the substrate with through holes filled with filler material 104 and forming a cap 112, and metal plating 114 disposed on the bottom side of the substrate and in contact with the cap.

In this embodiment, this invention is a process for forming an electrical interconnect on a substrate comprising: (A) providing a substrate for an electronic device having one or more through holes with openings at both the top and bottom surfaces of the substrate; (B) deposing a conductive filler material over the top surface of the substrate; (C) pressing the conductive filler material onto the top surface and into the through holes to cause the conductive filler material to protrude from the through holes at the bottom surface of the substrate in an amount to form a cap of sufficient size to perform as a bonding pad without the need to etch back the substrate near the cap.

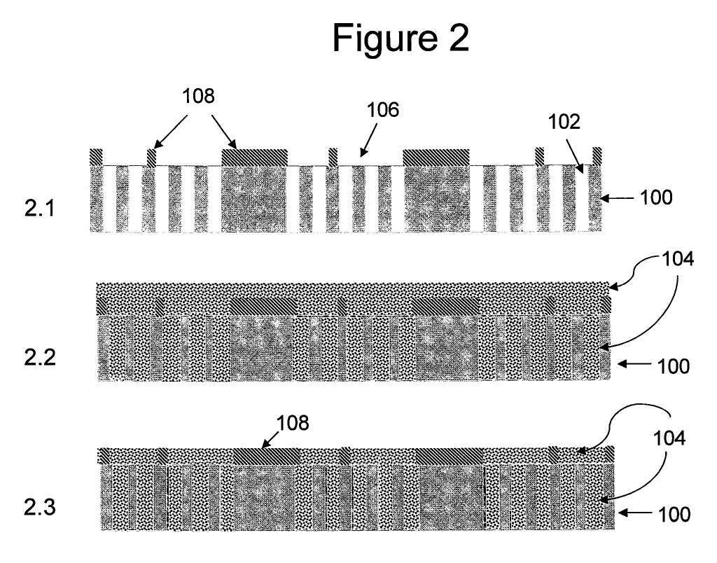

In another post through hole interconnect coating process, a dielectric mask is deposed on the substrate surface prior to filling the through hole interconnects. The through hole interconnects are filled, and the excess on the surface is removed down to the level of the dielectric mask. Referring to FIG. 2, drawing 2.1 shows a mask 108 deposed on the surface 106 of a substrate 100 containing through holes 102; drawing 2.2 shows the deposition of the filler material 104 in the through holes (element 102 as shown in drawing 2.1) and over the substrate surface (element 106 as shown in drawing 2.1) and mask (element 108 as shown in drawing 2.1); and drawing 2.3 shows the substrate 100 with the filler material 104 deposed on the surface at the level of the mask 108.

In this embodiment, this invention is a process for forming an electrical interconnect on a substrate comprising: (A) providing a substrate for an electronic device having one or more through hole interconnects; (B) disposing a mask on the surface; (C) deposing a conductive filler material over a surface of the substrate; (D) pressing the conductive film onto the surface and the mask and into the through holes; and (E) removing the excess residue of the conductive film down to the level of the mask.

In another post through hole interconnect coating process, filler material remaining on the top of the substrate can be used as a seed plate for forming a redistribution or interconnect layer, which is a metallic layer used for routing circuitry to the through hole interconnects of other substrates.

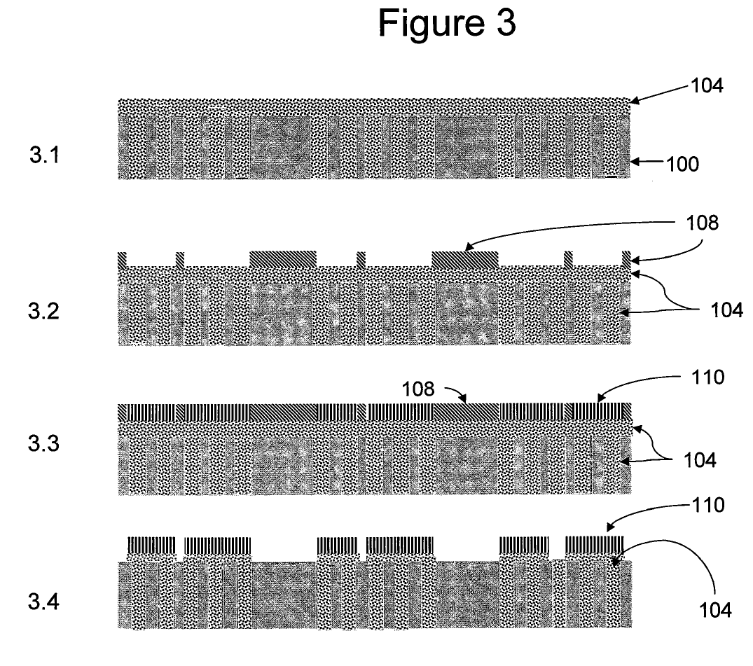

Referring to FIG. 3, drawing 3.1 shows a substrate 100 having filler material 104 in through holes (element 102 as shown in drawing 2.1) and on the substrate surface (element 106 as shown in drawing 2.1); drawing 3.2 shows the same elements with a mask 108 deposed on the surface filler material 104; drawing 3.3 shows a metallic plating 110 formed on the surface filler material 104; and drawing 3.4 shows the substrate with filler material 104 in the through holes (element 102 as shown in drawing 2.1), and metallic plating 110 formed on the surface filler material 104 after the plating mask and excess residue of the surface filler material are removed.

Thus, in this embodiment, this invention is a process for electroplating a substrate comprising: (A) providing a substrate for an electronic device having one or more through hole interconnects; (B) deposing a conductive filler material over a surface of the substrate; (C) pressing the conductive filler material onto the surface and into the through hole interconnects; (D) deposing a mask over the conductive filler material on the surface; (E) using the conductive filler material as a seed plate and electroplating a metal layer over the conductive filler material in the pattern provided by the mask; and (F) removing the mask and the excess residue of the conductive filler material.

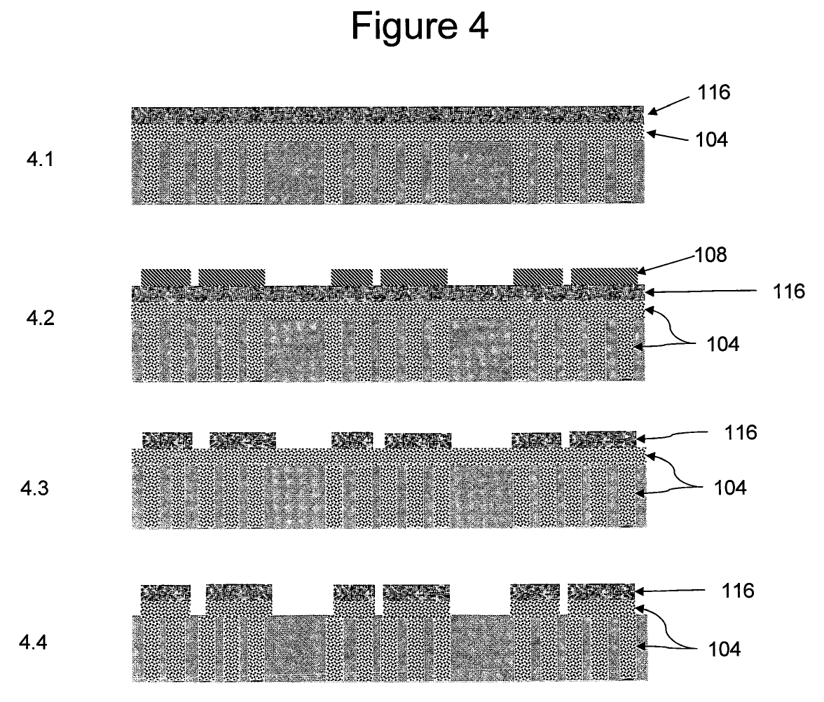

In a further post through hole interconnect process, a laminate of metal foil and filler material are applied at one time and the metal foil etched to a desired pattern. Referring to FIG. 4, drawing 4.1 shows a metal foil 116 previously laminated to a filler material 104 of a certain thickness, the laminate pressed onto the surface of a substrate 100 and into through hole interconnects 102, with a layer of the filler material and the metal foil remaining on the surface of the substrate; drawing 4.2 shows a mask 108 deposed on the metal foil; drawing 4.3 shows the resultant etched pattern in the metal foil; drawing 4.4 shows the resultant etched pattern in the filler material.

Thus, in a further embodiment, this invention is a process for forming a first layer interconnect on a substrate comprising: (A) providing a substrate for an electronic device having one or more through holes; (B) deposing a laminate of a metal foil and a conductive film over a surface of the substrate with the conductive film in contact with the surface; (C) pressing the laminate onto the surface and into the through hole interconnects to the extent that only the conductive film penetrates the through hole interconnects; (D) disposing a mask over the metal foil and conductive film on the surface with the mask in contact with the metal film; (F) etching the metal foil and removing the mask; (G) etching the conductive film in the same pattern as the metal foil.

Specimens were prepared using the following procedures. All substrates were glass or silicon. The through holes had diameters of 50 μm and were 250 μm deep. The filler material was either a conductive film or a composite of a conductive film and a dielectric film. The conductive film was a silver filled die attach material, 15 μm thick (product C100, Henkel Corp.). The dielectric film was a nonconductive dielectric film, 20 μm thick (product ATB 120, Henkel Corp.). When used as a laminate composite, the two films were laminated at 60° C. The conductive film or the laminate composite film was pressed into the substrate using a hot press at 0.62 megaPascal (90 psi) with or without vacuum, and then cured at 180° C. for one hour.

1. A method for filling through hole interconnects in a substrate for an electronic device comprising:
A. providing a substrate for an electronic device having one or more through hole interconnects;
B. providing a film comprising at least one filler material for the through hole interconnects; and
C. deposing the film over the substrate and pressing the film onto the surface and into the through hole interconnects.

2. The method according to claim 1 in which the filler material is in the form of a film comprising a resin matrix and conductive or non-conductive particles.

3. The method according to claim 2 in which the particles are conductive and selected from the group consisting of carbon black, graphite, gold, silver, copper, platinum, palladium, nickel, aluminum, silver plated copper, silver plated aluminum, bismuth, tin, bismuth-tin alloy, silver plated fiber, silicon carbide, boron nitride, diamond, alumina, and alloy 42.

4. The method according to claim 3 in which the conductive particles are selected from the group consisting of silver, silver plated copper, copper, gold, and alloy 42.

5. The method according to claim 3 in which the particles are nonconductive and selected from the group consisting of vermiculite, mica, wollastonite, calcium carbonate, titania, sand, glass, fused silica, fumed silica, barium sulfate, and halogenated ethylene polymers, such as tetrafluoroethylene, trifluoroethylene, vinylidene fluoride, vinyl fluoride, vinylidene chloride, and vinyl chloride.

6. The method according to claim 1 in which the film comprises two or more layers of the same or different filler material.

7. The method according to claim 6 in which one of the layers comprises a film comprising a resin matrix and conductive particles, and the other of the layers comprises a film comprising dielectric resin or a resin matrix filled with dielectric compounds.

8. The method according to claim 1 in which the film is pressed into the through hole interconnect as vacuum is applied to the opposite end of the through hole interconnect.

9. The method according to claim 1 in which the film is a two layer film, in which one layer is conductive and comprises a resin matrix and a conductive filler material, and a second layer is dielectric and comprises a resin matrix and dielectric filler; the film is disposed on the substrate with the dielectric layer in contact with the substrate and pressed into the through hole interconnect, whereby the dielectric layer is pushed into contact with the substrate and the conductive layer is insulated from the substrate.

10. The method according to claim 1 in which the substrate comprises semiconductor material.

11. The method according to claim 1 in which the substrate is glass or plastic.

12. A process for electroplating a substrate comprising:
(A) providing a substrate for an electronic device having one or more through hole interconnects;
(B) deposing a conductive filler material over a surface of the substrate;
(C) pressing the conductive filler material onto the surface and into the through hole interconnects;
(D) deposing a mask over the conductive filler material on the surface;
(E) using the conductive filler material as a seed plate and electroplating a metal layer over the conductive filler material in the pattern provided by the mask; and
(F) removing the mask and the excess residue of the conductive filler material.

13. A process for forming an electrical interconnect on a substrate comprising:
(A) providing a substrate for an electronic device having one or more through hole interconnects;
(B) disposing a mask on the surface;
(C) deposing a conductive filler material over a surface of the substrate;
(D) pressing the conductive film onto the surface and the mask and into the through holes; and
(E) removing the excess residue of the conductive film down to the level of the mask.

14. A process for forming an electrical interconnect on a substrate comprising:
(A) providing a substrate for an electronic device having one or more through holes with openings at both the top and bottom surfaces of the substrate;
(B) deposing a conductive filler material over the top surface of the substrate;
(C) pressing the conductive filler material onto the top surface and into the through holes to cause the conductive filler material to protrude from the through holes at the bottom surface of the substrate in an amount to form a cap of sufficient size to perform as a bonding pad without the need to etch back the substrate near the cap.

15. A process for forming a first layer interconnect on a substrate comprising:
(A) providing a substrate for an electronic device having one or more through holes;
(B) deposing a laminate of a metal foil and a conductive film over a surface of the substrate with the conductive film in contact with the surface;
(C) pressing the laminate onto the surface and into the through hole interconnects to the extent that only the conductive film penetrates the through hole interconnects;
(D) disposing a mask over the metal foil and conductive film on the surface with the mask in contact with the metal film;
(F) etching the metal foil and removing the mask;
(G) etching the conductive film.
